(19) United States
(12) Patent Application Publication
(10) Pub. No.: US 2026/0162932 A1
(43) Pub. Date: Jun. 11, 2026

(54) MULTIPLE CHARGED-PARTICLE BEAM APPARATUS AND METHODS OF OPERATING THE SAME

(71) Applicant: ASML Netherlands B.V., Veldhoven (NL)

(72) Inventors: Xiaoyu JI, San Jose, CA (US); Weiming REN, San Jose, CA (US)

(73) Assignee: ASML Netherlands B.V., Veldhoven (NL)

(21) Appl. No.: 18/706,364

(22) PCT Filed: Oct. 4, 2022
(86) PCT No.: PCT/EP2022/077559

§ 371 Date: Apr. 30, 2024

Related U.S. Application Data
(60) Provisional application No. 63/274,895, filed on Nov. 2, 2021.

(51) Int. Cl. H01J 37/147; H01J 37/12; H01J 37/141; H01J 37/153; H01J 37/28

(52) U.S. Cl. CPC H01J 37/1474; H01J 37/12; H01J 37/141; H01J 37/153; H01J 37/28; H01J 2237/0453; H01J 2237/04922; H01J 2237/04924; H01J 2237/1532; H01J 2237/1534; H01J 2237/2817

(57) ABSTRACT

Systems and methods of inspecting a sample using a multi charged-particle beam apparatus with enhanced probe current of beamlets are disclosed. The apparatus may include a charged-particle source, a first condenser lens configured to focus the plurality of charged-particle beams to form a beam crossover at a crossover point and a second condenser lens configured to collimate the focused plurality of charged-particle beams, wherein the crossover point is formed between the first and the second condenser lens along the primary optical axis, and wherein an adjustment of a position of the crossover point causes an adjustment of a beam sizes of the plurality of charged-particle beams. The position of the crossover point may be adjusted by varying the excitation of one or more condenser lenses, or by electrically moving the principal plane positions of one or more condenser lenses.

### CROSS-REFERENCE TO RELATED APPLICATIONS

This application claims priority of U.S. application 63/274,895 which was filed on 2 Nov. 2021 and which is incorporated herein in its entirety by reference.

### TECHNICAL FIELD

The embodiments provided herein disclose a multi-beam apparatus, and more particularly a multi-beam inspection apparatus with enhanced probe current of beamlets using a crossover mode for voltage-contrast inspection of defects.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important. Although multiple electron beams may be used to increase the throughput, the probe current for each beamlet may be insufficient for voltage-contrast inspection in VNAND or 3D-NAND structures, rendering the inspection apparatus inefficient, or in some cases, inadequate for their desired purpose.

### SUMMARY

One aspect of the present disclosure is directed to a multiple charged particle beam apparatus to inspect a sample. The apparatus may include a charged-particle source configured to generate a plurality of charged-particle beams along a primary optical axis, a first condenser lens configured to focus the plurality of charged-particle beams to form a beam crossover at a crossover point, and a second condenser lens configured to collimate the focused plurality of charged-particle beams, wherein the crossover point is formed between the first and the second condenser lens relative to the primary optical axis, and wherein an adjustment of a position of the crossover point causes an adjustment of beam sizes of the plurality of charged-particle beams.

Another aspect of the present disclosure is directed to a method of inspecting a sample using a multiple charged-particle beam apparatus. The method may include generating a plurality of charged-particle beams along a primary optical axis from a charged-particle source, focusing, using a first condenser lens, the plurality of charged-particle beams to form a beam crossover at a crossover point, adjusting a position of the crossover point to adjust beam sizes of the plurality of charged-particle beams, and collimating, using a second condenser lens, the focused plurality of charged-particle beams, wherein the crossover point is formed between the first and the second condenser lens relative to the primary optical axis.

Yet another aspect of the present disclosure is directed to a non-transitory computer readable medium storing a set of instructions that is executable by one or more processors of a multiple charged-particle beam apparatus to cause the multiple charged particle beam apparatus to perform a method. The method may include activating a charged-particle source to generate a plurality of charged-particle beams along a primary optical axis, focusing the plurality of charged-particle beams to form a beam crossover at a crossover point, adjusting a position of the crossover point to adjust beam sizes of the plurality of charged-particle beams, and collimating the focused plurality of charged-particle beams, wherein the crossover point is formed between a first and a second condenser lens of a condenser lens assembly and along the primary optical axis.

Yet another aspect of the present disclosure is directed to a multiple charged-particle beam apparatus. The apparatus may include a charged-particle source configured to generate a plurality of charged-particle beams along a primary optical axis; a first condenser lens configured to focus the plurality of charged-particle beams to form a beam crossover; and a second condenser lens configured to collimate the focused plurality of charged-particle beams, wherein the beam crossover is formed between the first and the second condenser lens relative to the primary optical axis, and wherein the collimated plurality of charged-particle beams is used to flood a surface of a sample with charged particles and to inspect the flooded surface of the sample Yet another aspect of the present disclosure is directed to a method of inspecting a sample using a multiple charged-particle beam apparatus. The method may include generating a plurality of charged-particle beams along a primary optical axis from a charged-particle source, focusing, using a first condenser lens, the plurality of charged-particle beams to form a beam crossover at a crossover point, collimating, using a second condenser lens, the focused plurality of charged-particle beams; flooding a surface of the sample with a portion of charged particles from the collimated plurality of charged-particle beams; and inspecting the flooded surface using the portion of charged particles.

Yet another aspect of the present disclosure is directed to a non-transitory computer readable medium storing a set of instructions that is executable by one or more processors of a multiple charged-particle beam apparatus to cause the multiple charged particle beam apparatus to perform a method. The method may include generating a plurality of charged-particle beams along a primary optical axis from a charged-particle source, focusing, using a first condenser lens, the plurality of charged-particle beams to form a beam crossover, collimating, using a second condenser lens, the focused plurality of charged-particle beams, flooding a surface of the sample with a portion of charged particles from the collimated plurality of charged-particle beams, and inspecting the flooded surface using the portion of charged particles.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a schematic diagram illustrating an exemplary electron beam inspection (EBI) system, consistent with embodiments of the present disclosure.

FIG. 2 is a schematic diagram illustrating an exemplary electron beam tool that can be a part of the exemplary electron beam inspection system of FIG. 1, consistent with embodiments of the present disclosure.

FIGS. 3A-3C are schematic diagrams illustrating exemplary configurations of a condenser lens assembly in a multi-beam apparatus, consistent with embodiments of the present disclosure.

FIGS. 4A-4B are schematic diagrams illustrating exemplary configurations of a beam-limit aperture array in a multi-beam apparatus, consistent with embodiments of the present disclosure.

FIG. 5 is a schematic diagram illustrating an exemplary multi-beam apparatus including a lens array, consistent with embodiments of the present disclosure.

FIG. 6 is a schematic diagram illustrating an exemplary multi-beam apparatus including a deflector array, consistent with embodiments of the present disclosure.

FIG. 7 is a schematic diagram illustrating an exemplary multi-beam apparatus including a beam-shift deflector array, consistent with embodiments of the present disclosure.

FIG. 8 is a process flowchart representing an exemplary method of inspecting a sample using a beam crossover mode in a multi-beam apparatus, consistent with embodiments of the present disclosure.

FIG. 9 is a process flowchart representing an exemplary method of inspecting a sample using a beam crossover mode in a multi-beam apparatus, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

Detecting buried defects in vertical high-density structures such as 3D NAND flash memory devices, can be challenging. One of several ways to detect buried or on-surface electrical defects in such devices is by using a voltage contrast method in a SEM. In this method, electrical conductivity differences in materials, structures, or regions of a sample cause contrast differences in SEM images thereof. In the context of defect detection, an electrical defect under the sample surface may generate a charging variation on the sample surface, so the electrical defect can be detected by a contrast in the SEM image of the sample surface. To enhance the voltage contrast, a process called pre-charging or flooding may be employed in which the region of interest of the sample may be exposed to a large current beam before an inspection using a small current but high imaging resolution beam. For the inspection, some of the advantages of flooding may include uniform charging of the wafer to minimize distortion of images due to charging effects, and in some cases, increase of charging of the wafer to enhance difference of defective and surrounding non-defective features in images, among other things.

Though the voltage-contrast technique is useful in detecting buried or on-surface electrical defects in complex device structures, the technique may suffer from some drawbacks. The voltage-contrast defect detection technique is performed in two discrete steps-the first step involves flooding or pre-charging a sample with a large beam current, followed by an inspection step using the primary probe beams with low beam current. This two-step process may not only negatively impact the throughput of the inspection process, but the low beam current probes may also be inadequate for the inspection of three-dimensional, high-aspect ratio structures commonly employed in 3D NAND or VNAND devices.

In currently existing SEMs, some of the ways to obtain larger probe beam currents include increasing the intensity of the electron source emission or increasing the diameter of the beam-limiting apertures to allow more electrons to pass through. However, these techniques may introduce electron source instability and image quality deterioration, both of which may negatively impact the throughput of the process. For example, increasing the intensity of the electron source emission may cause instability of the source, affecting the performance and reliability of the inspection tool. Further, the number of available beamlets in the normal probe current range may be reduced as well. Increasing the diameter of the beam-limiting apertures may increase the aberrations such as field curvature, astigmatism, among other things, of image-forming elements (e.g., micro-lens arrays, or deflector arrays). The increased aberrations may cause deterioration in image resolution, thereby impacting the defect detection capabilities of the inspection apparatus. Therefore, it may be desirable to increase the beam current of individual beamlets using a technique that improves the detection efficiency, while maintaining the high throughput and image resolution.

In some embodiments of the present disclosure, a multi-beam apparatus, operating in a crossover mode, may include a condenser lens assembly comprising a first condenser lens and a second condenser lens. The first condenser lens may be configured to focus the primary charged-particle beam (e.g., a primary electron beam) generated from the charged-particle source, to form a beam crossover at a crossover point along a primary optical axis. The beam crossover may be formed between the first and the second condenser lens. The beam current may be adjusted based on the excitation of the first condenser lens, or a combined excitation of the first and the second condenser lens. The change in excitation causes a change in the focusing power of the condenser lenses, resultantly adjusting the position of the beam crossover. The second condenser lens may be configured to focus and collimate the primary electron beam. Because the primary electron beam is compacted and combined to form a beam crossover, fewer primary electron beamlets may be generated, but the beamlet current or the beamlet current density of each beamlet may be higher than the corresponding beamlet in the non-crossover mode.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

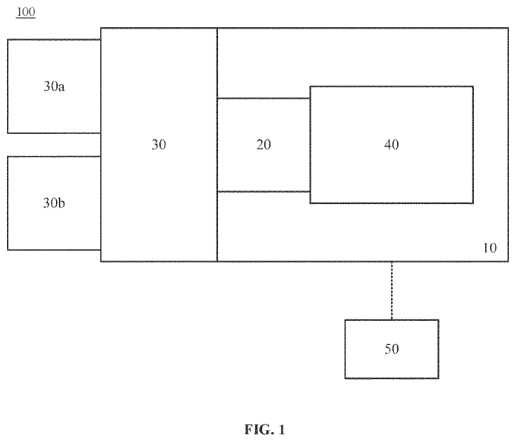

Reference is now made to FIG. 1, which illustrates an exemplary electron beam inspection (EBI) system 100 consistent with embodiments of the present disclosure. As shown in FIG. 1, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles and charged-particle beam apparatuses. For example, a charged-particle may refer to an electron, an ion, or any positively or negatively charged particle and a charged-particle beam apparatus may refer to an electron beam apparatus, or an ion beam apparatus, or any apparatus using electrons and ions such as a SEM, or a focused ion beam (FIB) in combination with SEM.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool. In other embodiments, electron beam tool 40 may comprise a multi-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1 as being outside of the structure that includes main chamber 10, load-lock chamber 20, and EFEM 30, it is appreciated that controller 50 can be part of the structure.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well.

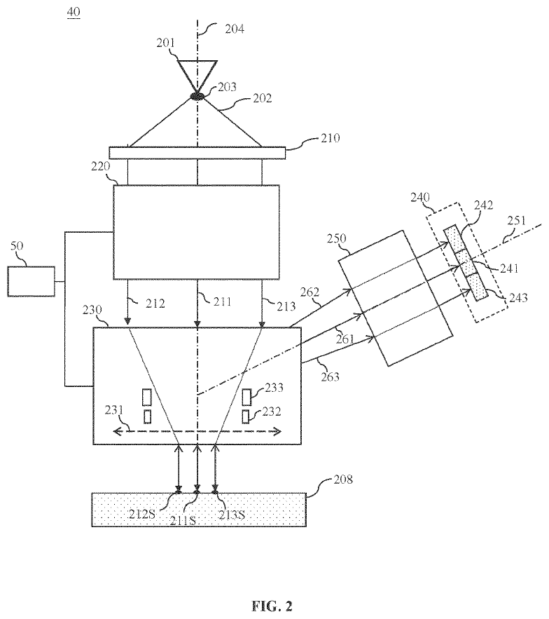

Reference is now made to FIG. 2, which illustrates a schematic diagram illustrating an exemplary electron beam tool 40 that can be a part of the exemplary charged particle beam inspection system 100 of FIG. 1, consistent with embodiments of the present disclosure. Electron beam tool 40 (also referred to herein as apparatus 40) may comprise an electron source 201, a condenser lens 210, a source conversion unit 220, a primary projection optical system 230, a secondary imaging system 250, and an electron detection device 240. It may be appreciated that other commonly known components of apparatus 40 may be added/omitted as appropriate.

Although not shown in FIG. 2, in some embodiments, electron beam tool 40 may comprise a gun aperture plate, a pre-beamlet forming mechanism, a motorized sample stage, a sample holder to hold a sample (e.g., a wafer or a photomask).

Electron source 201, condenser lens 210, source conversion unit 220, deflection scanning unit 232, beam separator 233, and primary projection optical system 230 may be aligned with a primary optical axis 204 of apparatus 40. Secondary imaging system 250 and electron detection device 240 may be aligned with a secondary optical axis 251 of apparatus 40.

Electron source 201 may include a cathode, an extractor or an anode, wherein primary electrons can be emitted from the cathode and extracted or accelerated to form a primary electron beam 202 that forms a primary beam crossover (virtual or real) 203. Primary electron beam 202 can be visualized as being emitted from primary beam crossover 203.

Condenser lens 210 may be configured to focus primary electron beam 202. In some embodiments, condenser lens 210 may be configured as an adjustable condenser lens such that the position of a principal plane along which condenser lens 210 is located is movable. In some embodiments, condenser lens 210 may be configured to focus a received portion of primary electron beam 202 based on a selected mode of operation such as, flooding, inspection, etc. Condenser lens 210 may comprise an electrostatic, electromagnetic, or a compound electromagnetic lens, among others. In some embodiments, condenser lens 210 may be electrically or communicatively coupled with a controller, such as controller 50 illustrated in FIG. 2. Controller 50 may apply an electrical excitation signal to condenser lens 210 to adjust the focusing power of condenser lens 210. The electromagnetic compound lens may include a magnetic portion and an electrostatic portion. The magnetic portion may include a permanent magnet. The compound lens may allow its focusing power to be provided partially by the magnetic portion and partially by the electrostatic portion, and an adjustable part of the focusing power may be provided by the electrostatic portion.

Source conversion unit 220 may comprise an aperture lens array, a beam-limit aperture array, and an imaging lens. The aperture lens array may comprise an aperture-lens forming electrode plate and an aperture lens plate positioned below the aperture-lens forming electrode plate. In this context, “below” refers to the structural arrangement such that primary electron beam 202 traveling downstream from electron source 201 irradiates the aperture-lens forming electrode plate before the aperture lens plate. The aperture-lens forming electrode plate may be implemented via a plate having an aperture configured to allow at least a portion of primary electron beam 202 to pass through. The aperture lens plate may be implemented via a plate having a plurality of apertures traversed by primary electron beam 202 or multiple plates having plurality of apertures. The aperture-lens forming electrode plate and the aperture lens plate may be excited to generate electric fields above and below the aperture lens plate. The electric field above the aperture lens plate may be different from the electric field below the aperture lens plate so that a lens field is formed in each aperture of the aperture lens plate, and the aperture lens array may thus be formed.

In some embodiments, the beam-limit aperture array may comprise beam-limit apertures. It is appreciated that any number of apertures may be used, as appropriate. The beam-limit aperture array may be configured to limit diameters of individual primary beamlets 211, 212, and 213. Although FIG. 2 shows three primary beamlets 211, 212, and 213 as an example, however, it is appreciated that source conversion unit 220 may be configured to form any number of primary beamlets.

In some embodiments, an imaging lens may comprise a collective imaging lens configured to focus primary beamlets 211, 212, and 213 on an image plane. Imaging lens may have a principal plane orthogonal to primary optical axis 204. Imaging lens may be positioned below beam-limit aperture array and may be configured to focus primary beamlets 211, 212, and 213 such that the beamlets form a plurality of focused images of primary electron beam 202 on the intermediate image plane.

Primary projection optical system 230 may comprise an objective lens 231, a deflection scanning unit 232, a beamlet control unit (not shown), and a beam separator 233. Beam separator 233 and deflection scanning unit 232 may be positioned inside primary projection optical system 230. Objective lens 231 may be configured to focus beamlets 211, 212, and 213 onto sample 208 for inspection and can form three probe spots 211S, 212S, and 213S, respectively, on surface of sample 208. In some embodiments, beamlets 211, 212, and 213 may land normally or substantially normally on objective lens 231. In some embodiments, focusing by the objective lens may include reducing the aberrations of the probe spots 211S, 212S, and 213S.

In response to incidence of primary beamlets 211, 212, and 213 on probe spots 211S, 212S, and 213S on sample 208, electrons may emerge from sample 208 and generate three secondary electron beams 261, 262, and 263. Each of secondary electron beams 261, 262, and 263 typically comprise secondary electrons (having electron energy≤50 eV) and backscattered electrons (having electron energy between 50 eV and the landing energy of primary beamlets 211, 212, and 213).

Electron beam tool 40 may comprise beam separator 233. Beam separator 233 may be of Wien filter type comprising an electrostatic deflector generating an electrostatic dipole field E1 and a magnetic dipole field B1 (both of which are not shown in FIG. 2). If they are applied, the force exerted by electrostatic dipole field El on an electron of beamlets 211, 212, and 213 is equal in magnitude and opposite in direction to the force exerted on the electron by magnetic dipole field B1. Beamlets 211, 212, and 213 can therefore pass straight through beam separator 233 with zero deflection angles.

Deflection scanning unit 232 may be configured to deflect beamlets 211, 212, and 213 to scan probe spots 211S, 212S, and 213S over three small scanned areas in a section of the surface of sample 208. Beam separator 233 may direct secondary electron beams 261, 262, and 263 towards secondary imaging system 250. Secondary imaging system 250 can focus secondary electron beams 261, 262, and 263 onto detection elements 241, 242, and 243 of electron detection device 240. Detection elements 241, 242, and 243 may be configured to detect corresponding secondary electron beams 261, 262, and 263 and generate corresponding signals used to construct images of the corresponding scanned areas of sample 208.

In FIG. 2, three secondary electron beams 261, 262, and 263 respectively generated by three probe spots 211S, 212S, and 213S, travel upward towards electron source 201 along primary optical axis 204, pass through objective lens 231 and deflection scanning unit 232 in succession. The three secondary electron beams 261, 262, and 263 are diverted by beam separator 233 (such as a Wien Filter) to enter secondary imaging system 250 along secondary optical axis 251 thereof. Secondary imaging system 250 may focus the three secondary electron beams 261, 262, and 263 onto electron detection device 140 which comprises three detection elements 241, 242, and 243. Therefore, electron detection device 240 can simultaneously generate the images of the three scanned regions scanned by the three probe spots 211S, 212S, and 213S, respectively. In some embodiments, electron detection device 240 and secondary imaging system 250 form one detection unit (not shown). In some embodiments, the electron optics elements on the paths of secondary electron beams such as, but not limited to, objective lens 231, deflection scanning unit 232, beam separator 233, secondary imaging system 250 and electron detection device 240, may form one detection system.

In some embodiments, controller 50 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 240 of apparatus 40 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 240 and may construct an image. The image acquirer may thus acquire images of sample 208 or features disposed on surface of sample 208. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on an imaging signal received from electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time sequence. The multiple images may be stored in the storage. In some embodiments, controller 50 may be configured to perform image processing steps with the multiple images of the same location of sample 208.

In some embodiments, controller 50 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213, incident on the wafer surface, can be used to reconstruct images of the wafer structures under inspection. The reconstructed images can be used to reveal various features of the internal or external structures of sample 208, and thereby can be used to reveal any defects that may exist in the wafer.

In some embodiments, controller 50 may control a motorized stage (not shown) to move sample 208 during inspection. In some embodiments, controller 50 may enable the motorized stage to move sample 208 in a direction continuously at a constant speed. In other embodiments, controller 50 may enable the motorized stage to change the speed of the movement of sample 208 over time depending on the steps of scanning process. In some embodiments, controller 50 may adjust a configuration of primary projection optical system 230 or secondary imaging system 250 based on images of secondary electron beams 261, 262, and 263.

In some embodiments, primary projection optical system 230 may comprise beamlet control unit configured to receive primary beamlets 211, 212, and 213 from source conversion unit 220 and direct them towards sample 208. Beamlet control unit may include a transfer lens (not shown) configured to direct primary beamlets 211, 212, and 213 from the image plane to the objective lens such that primary beamlets 211, 212, and 213 normally or substantially normally land on surface of sample 208, or form the plurality of probe spots 221, 222, and 223 with small aberrations. Transfer lens may be a stationary or a movable lens. In a movable lens, the focusing power of the transfer lens may be changed by adjusting the electrical excitation of the lens.

In some embodiments, beamlet control unit may comprise a beamlet tilting deflector configured to may be configured to tilt primary beamlets 211, 212, and 213 to obliquely land on the surface of sample 208 with same or substantially same landing angles (O) with respect to the surface normal of sample 208. Tilting the beamlets may include shifting a crossover of primary beamlets 211, 212, and 213 slightly off primary optical axis 204. This may be useful in inspecting samples or regions of sample that include three-dimensional features or structures such as side walls of a well, or a trench, or a mesa structure.

In some embodiments, beamlet control unit may comprise a beamlet adjustment unit (not shown) configured to compensate for aberrations such as astigmatism and field curvature aberrations caused due to one or all of the lenses mentioned above. Beamlet adjustment unit may comprise an astigmatism compensator array, a field curvature compensator array, and a deflector array. The field curvature compensator array may comprise a plurality of micro-lenses to compensate field curvature aberrations of the primary beamlets 211, 212, and 213, and the astigmatism compensator array may comprise a plurality of micro-stigmators to compensate astigmatism aberrations of the primary beamlets 211, 212, and 213.

In some embodiments, the deflectors of the deflector array may be configured to deflect beamlets 211, 212, and 213 by varying angles towards primary optical axis 204. In some embodiments, deflectors farther away from primary optical axis 204 may be configured to deflect beamlets to a greater extent. Furthermore, deflector array may comprise multiple layers (not illustrated), and deflectors may be provided in separate layers. Deflectors may be configured to be individually controlled independent from one another. In some embodiments, a deflector may be controlled to adjust a pitch of probe spots (e.g., 221, 222, and 223) formed on a surface of sample 208. As referred to herein, pitch of the probe spots may be defined as the distance between two immediately adjacent probe spots on the surface of sample 208. In some embodiments, the deflectors may be placed on the intermediate image plane.

In some embodiments, controller 50 may be configured to control source conversion unit 220 and primary projection optical system 230, as illustrated in FIG. 2. Although not illustrated, controller 50 may be configured to control one or more components of electron beam tool 40 including, but not limited to, electron source 201 and components of source conversion unit 220, primary projection optical system 230, electron detection device 240, and secondary imaging system 250. Although FIG. 2 shows that electron beam tool 40 uses three primary electron beamlets 211, 212, and 213, it is appreciated that electron beam tool 40 may use two or more primary electron beamlets. The present disclosure does not limit the number of primary electron beamlets used in apparatus 40.

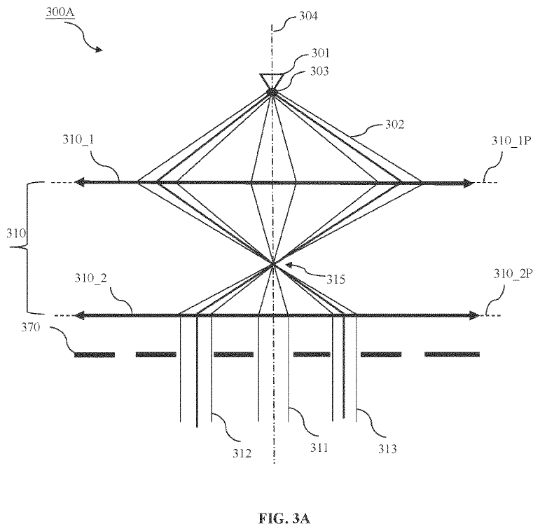

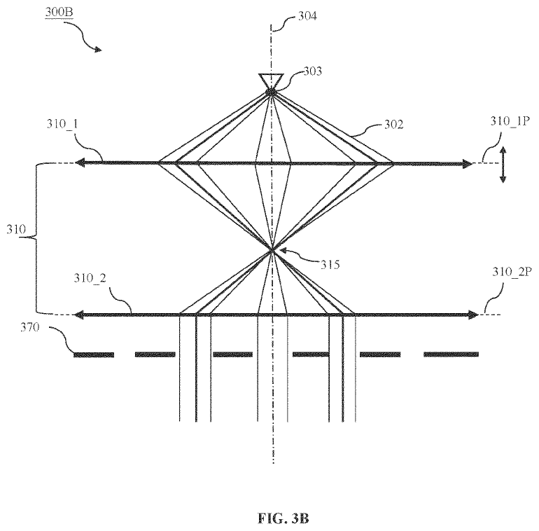

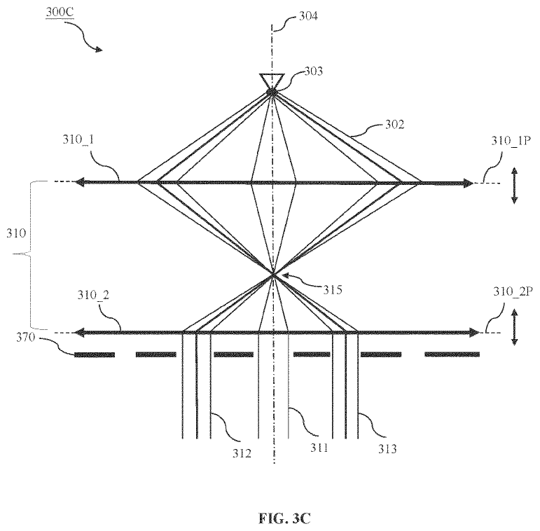

Reference is now made to FIGS. 3A-3C, which are schematic diagrams of exemplary configurations of a condenser lens assembly 310 in a multi-beam apparatus, consistent with embodiments of the present disclosure. In the embodiment shown in FIG. 3A, multi-beam apparatus 300A, also referred to herein as electron-optics system 300A or apparatus 300A may comprise electron source 301 configured to generate primary electron beam 302, a condenser lens assembly 310, and a beam-limit aperture array 370, among other things (not shown). It is appreciated that electron source 301, primary electron beam 302, and beam-limit aperture array 370 may be similar or substantially similar to the corresponding elements described in FIG. 2 and may perform similar functions. Although not illustrated, apparatuses 300A, 300B, and 300C of FIGS. 3A, 3B, and 3C, respectively, may further include a primary projection optical system, a secondary imaging system, and an electron detection device, among other components as appropriately needed.

Electron source 301 may be configured to emit primary electrons (exemplary charged-particles) from a cathode and extracted or accelerated to form primary electron beam 302 (exemplary charged-particle beam) that forms a primary beam crossover (virtual or real) 303. In some embodiments, primary electron beam 302 can be visualized as being emitted from primary beam crossover 303 along a primary optical axis 304. In some embodiments, one or more elements of apparatus 40 may be aligned with primary optical axis 304. Source conversion unit (not shown) may include beam-limit aperture array 370, among other elements. It is appreciated that source conversion unit may include one or more other optical or electro-optical elements as described in relation to FIG. 2.

Referring to FIG. 3A, condenser lens assembly 310 of apparatus 300A may include two condenser lenses 310_1 and 310_2, disposed on principal planes 310_1P and 310_2P, respectively. Principal planes 310_1P and 310_2P may be substantially parallel to each other and substantially perpendicular to primary optical axis 304. As used herein, “substantially perpendicular” refers to the degree of orthogonality between planes, axes, or between a plane and an axis. For example, the angle subtended by a principal plane of a condenser lens substantially perpendicular to a primary optical axis may be 90°±0.01°, or the standard deviation may be even smaller such that the angle is essentially 90°. As used herein, “substantially parallel” indicates that the planes are extended in the same direction such that the planes would never intersect each other and are essentially parallel. In some embodiments, condenser lens assembly 310 may be positioned immediately downstream of electron source 301. As used in the context of this disclosure, “downstream” refers to a position of an element along the path of primary electron beam 302 starting from electron source 301, and “immediately downstream” refers to a position of a second element along the path of primary electron beam 302 such that there are no other elements between the first and the second element. For example, as illustrated in FIG. 3A, condenser lens assembly 310 may be positioned immediately downstream of electron source 301 such that there are no other optical or electro-optical elements placed between electron source 301 and condenser lens assembly 310. Such a configuration may be useful, among other things, in reducing the height of the electro-optical column of apparatus 300A and in reducing the structural complexity thereof. In some embodiments, an aperture plate (e.g., a gun aperture plate) (not shown) may be placed between electron source 301 and condenser lens assembly 310 to block off peripheral electrons of primary electron beam 302 before being incident on condenser lens assembly 310, to reduce Coulomb interaction effects, among other things.

Large beamlet current may be desirable in detection of electrical defects using voltage contrast techniques in complex three-dimensional structures such as VNAND or 3D-NAND devices, among other things. One of several ways to achieve larger beamlet current may include operating the inspection system in a crossover mode. In a crossover mode of operation, as illustrated in FIGS. 3A-3C, electron source 301 may generate primary electron beam 302 traveling along primary optical axis 304. Condenser lens 310_1 may receive primary electron beam 302 and focus the electrons of primary electron beam 302 such that beam forms a crossover at a crossover point along primary optical axis 304. The location of beam crossover 315 may be adjusted based on an electrical excitation of condenser lens 310_1. Condenser lens 310_2 may be configured to collimate the focused primary electron beam 302 such that after exiting condenser lens 310_2, primary electron beam 302 is substantially parallel to primary optical axis 304. The collimated primary electron beam 302 is incident substantially perpendicular on beam-limit aperture array 370 and passes through a plurality of apertures of beam-limit aperture array 370 to generate a plurality of beamlets 311, 312, and 313. The beam current of primary electron beam 302 exiting condenser lens 310_2, and therefore the beam current of the plurality of beamlets, may be based on the position of beam crossover 315 along primary optical axis 304. For example, if beam crossover 315 is formed closer to condenser lens 310_1, the beam current of primary electron beam 302 may be smaller in comparison to beam crossover 315 being formed closer to condenser lens 310_2. This may be because, after being focused at beam crossover 315 closer to condenser lens 310_1, primary electron beam 302 may diverge more until it is collimated by condenser lens 310_2, resulting in more electrons of primary electron beam 302 being blocked by beam-limit aperture array 370. Although the number of beamlets generated in crossover mode may be smaller than the number of beamlets in the non-crossover mode (not discussed in this disclosure), however, the beam current of each beamlet in crossover mode may be larger in comparison to the beam current of each beamlet in non-crossover mode. This may be because, in comparison to non-crossover mode, the multiple beamlets of primary electron beam 302 are combined and compacted to form a beam with a smaller beam diameter, and therefore a higher beam current density.

In some embodiments, condenser lens 310_1 of condenser lens assembly 310 may be placed closer to electron source 301 and condenser lens 310_2 may be placed immediately downstream from condenser lens 310_1. Condenser lens 310_1 may be configured to receive and focus primary electron beam 302 such that a beam crossover 315 may be formed at a crossover point. The electrons of primary electron beam 302 may be focused such that the crossover point is between condenser lens 310_1 and condenser lens 310_2 along primary optical axis 304. The crossover point may substantially coincide with primary optical axis 304. In some embodiments, condenser lens 310_1 may comprise an electrostatic lens, a magnetic lens, or a compound electromagnetic lens, a movable lens, among other types of condenser lens.

In some embodiments, condenser lens 310_1 may be an electrostatic lens configured to focus primary electron beam 302 based on the focusing power of the electrostatic lens. The focusing power of condenser lens 310_1 may be adjusted based on the electrical excitation of the electrostatic lens. Focusing power, as used herein, refers to the degree to which the lens converges or diverges the incident particle (e.g., an electron). The electrical excitation of condenser lens 310_1 may be adjusted by applying or adjusting an applied electrical signal, typically a voltage signal, received from a controller (e.g., controller 50 of FIG. 2). Adjusting the electrical excitation may adjust the focusing power of condenser lens 310_1, which may change the convergence angle of primary electron beam 302, thereby adjusting the position of beam crossover 315 along primary optical axis 304. As an example, increasing the focusing power of condenser lens 310_1 by adjusting the applied electrical excitation signal may cause primary electron beam 302 to converge at a higher angle and to form beam crossover 315 closer to electron source 301 along primary optical axis 304. In contrast, decreasing the focusing power of condenser lens 310_1 by adjusting the electrical excitation signal may cause primary electron beam 302 to converge at a smaller angle and to form beam crossover 315 farther from electron source 301 along primary optical axis 304. Convergence angle, as used herein, refers to the angle formed by primary electron beam 302 after exiting condenser lens 310_1 with respect to primary optical axis 304.

Condenser lens assembly 310 may further comprise condenser lens 310_2 disposed downstream from condenser lens 310_1 and on principal plane 310_2P substantially perpendicular to primary optical axis 304. Condenser lens 310_2 may be disposed such that it is substantially parallel to condenser lens 310_1. In some embodiments, condenser lens 310_2 may be configured to collimate primary electron beam 302 after formation of beam crossover 315 by condenser lens 310_1.

In some embodiments, condenser lens 310_2 may be an electrostatic lens configured to collimate and focus primary electron beam 302 after beam crossover 315 is formed, based on the focusing power of the electrostatic lens. The focusing power of condenser lens 310_2 may be adjusted by adjusting an already applied electrical excitation signal or by applying an electrical excitation signal to condenser lens 310_2. In some embodiments, the excitation of condenser lens 310_2 may be determined based on factors including, but not limited to, excitation of condenser lens 310_1, position of beam crossover 315, or a distance between condenser lens 310_1 and condenser lens 310_2, among other factors.

In some embodiments, the axial position of beam crossover 315 may be based on a combination of lens settings of condenser lens 310_1 and condenser lens 310_2. Lens settings may include, but are not limited to, electrical excitation, position along primary optical axis, type of condenser lens, among other settings. As previously described, the axial position of beam crossover 315 may be adjusted to adjust the beam current of primary electron beam 302 exiting condenser lens assembly 310, and therefore, determining the beam current of each beamlet generated by beam-limit aperture array 370 and incident on a surface of a sample (e.g., sample 208 of FIG. 2) to form probe spots.

In some embodiments, the positions of principal planes 310_1P and 310_2P of condenser lenses 310_1 and 310_2, respectively, may be fixed and accordingly the distance between the two principal planes may also be substantially unchanged. In such a scenario, the position of beam crossover 315, and therefore the beam current of each individual beamlet may be adjusted by changing the excitation of condenser lens 310_1, or excitation of condenser lens 310_2, or both. In some embodiments, the position of beam crossover 315 may be adjusted within a range along primary optical axis 304 based on factors including, but not limited to, the excitation limitations of the condenser lenses, or the desirable beam current, among other things.

Reference is now made to FIG. 3B, which illustrates a schematic diagram of an exemplary configuration of a condenser lens assembly 310 in a multi-beam apparatus 300B, consistent with embodiments of the present disclosure. Condenser lens assembly 310 of multi-beam apparatus 300B may comprise condenser lens 310_1 implemented by a compound electromagnetic lens and condenser lens 310_2 implemented by an electrostatic lens.

Generally, a magnetic lens may generate less aberration than an electrostatic lens but may occupy more space than an electrostatic lens. Therefore, a compound electromagnetic lens may be employed in systems with physical space limitations and stricter aberration tolerances. A compound electromagnetic lens may include an electrostatic lens and a magnetic lens. The magnetic lens of the compound lens may include a permanent magnet. The magnetic lens of the compound lens may provide a portion of the total focusing power of the compound lens, while the electrostatic lens may make up the remaining portion of the total focusing power.

Condenser lens assembly 310 of multi-beam apparatus 300B may be configured to adjust the beam current of primary electron beam 302 or the beam current of the plurality of beamlets 311, 312, and 313. With reference to FIG. 3B, condenser lens 310_1 may be configured to focus primary electron beam 302 to form beam crossover 315 along primary optical axis 304. The beam current of primary electron beam 302 may be adjusted by adjusting the position of beam crossover 315 either by varying the electrical excitation of condenser lens 310_1, by electrically adjusting the position of principal plane of condenser lens 310_1, or a combination of both. The position of electromagnetic lens, as used herein, refers to the position of principal plane 310_1P along which condenser lens 310_1 is disposed.

In some embodiments, the beam current of primary electron beam 302 or the current of probe spots on the sample may be adjusted by moving principal plane 310_1P of condenser lens 310_1 and accordingly adjusting the focusing power of condenser lens 310_1, as illustrated in FIG. 3B. Condenser lens 310_2 of multi-beam apparatus 300B may be an electrostatic lens having a fixed principal plane 310_2P substantially perpendicular to primary optical axis 304. In some embodiments, the position of beam crossover 315, and therefore the beam current of individual beamlets 311, 312, and 313 may be adjusted by varying the excitation of electrostatic lens of electromagnetic lens, or the excitation of condenser lens 310_2, or by electrically moving principal plane 310_1P, or any combination thereof. The condenser lens assembly 310, as illustrated in FIG. 3B, may provide an extended range of positions of beam crossover 315 by employing a movable condenser lens 310_1.

Reference is now made to FIG. 3C, which illustrates a schematic diagram of an exemplary configuration of a condenser lens assembly 310 in a multi-beam apparatus 300C, consistent with embodiments of the present disclosure. In comparison to multi-beam apparatus 300B, each of the condenser lenses 310_1 and 310_2 of condenser lens assembly 310 may comprise a compound electromagnetic lens.

In some embodiments, the position of beam crossover 315 and accordingly the beam current of primary electron beam 302 or individual beamlets 311, 312, and 313 may be adjusted by electrically moving principal plane 310_1P of condenser lens 310_1, or electrically moving principal plane 310_2P of condenser lens 310_2, or the excitation of electrostatic lens of condenser lens 310_1, or the excitation of electrostatic lens of condenser lens 310_2, or any combination thereof. In some embodiments, the distance between principal planes 310_1P and 310_2P of condenser lens 310_1 and condenser lens 310_2, respectively, may be adjustable either by electrically moving principal plane 310_1P, or electrically moving principal planes 310_2P, or both. In the embodiment where both principal planes can be moved electrically, as illustrated in FIG. 3C, condenser lens assembly 310 configuration may provide a larger range of positions of beam crossover 315, and therefore, a larger range of beam currents of primary electron beam 302 or individual beamlets 311, 312, and 313. The condenser lens assembly 310 of multi-beam apparatus 300C may also provide more flexibility in device design considerations such as, but not limited to, addition of other optical or electro-optical components.

In some embodiments, multi-beam apparatuses 300A, 300B, and 300C, may further comprise beam-limit aperture array 370 configured to generate plurality of beamlets 311, 312, or 313 from incident primary electron beam 302 after exiting condenser lens assembly 310. Beam-limit aperture array 370 may include a plurality of apertures spaced apart to allow a portion of primary electron beam 302 to pass through while blocking the rest of the electrons. In some embodiments, beam-limit aperture array 370 may be implemented via a conducting planar structure such as, but not limited to, a metal plate with through holes.

In some embodiments, the beamlet current of primary beamlets 311, 312, and 313 may be further determined based on the sizes of the apertures of beam-limit aperture array 370 through which primary beamlets 311, 312, and 313 may be generated. In some embodiments, beam-limit aperture array 370 may comprise a plurality of beam-limit apertures having uniform sizes, shapes, cross-sections, or pitch. In some embodiments, the sizes, shapes, cross-sections, pitches, etc. may be non-uniform as well. The beam-limit apertures may be configured to limit the currents of beamlets by, for example, limiting the size of the beamlet or the number of electrons passing through the aperture based on the size or shape of the apertures.

In some embodiments, beam-limit aperture array 370 may be movable along an X-axis and a Y-axis in a plane orthogonal to primary optical axis 304 such that primary beamlets 311, 312, and 313 may be incident upon apertures of a desired shape and size. For example, beam-limit aperture array 370 may comprise a plurality of rows of apertures having a shape and a size, wherein apertures within each row have similar sizes and shapes. The position of beam-limit aperture array 370 may be adjusted so that a row of apertures having the desired sizes and shapes may be exposed to primary beamlets 311, 312, and 313. It is to be appreciated that though only three beamlets 311, 312, and 313 are illustrated in the cross-sectional schematics of the multi-beam apparatus of FIGS. 3A-3C, any appropriate number of beamlets may be generated.

In some embodiments, beam-limit aperture array 370 may be disposed downstream from condenser lens assembly 310 such that the collimated primary electron beam 302 exiting condenser lens 310_2 is directly and perpendicularly incident.

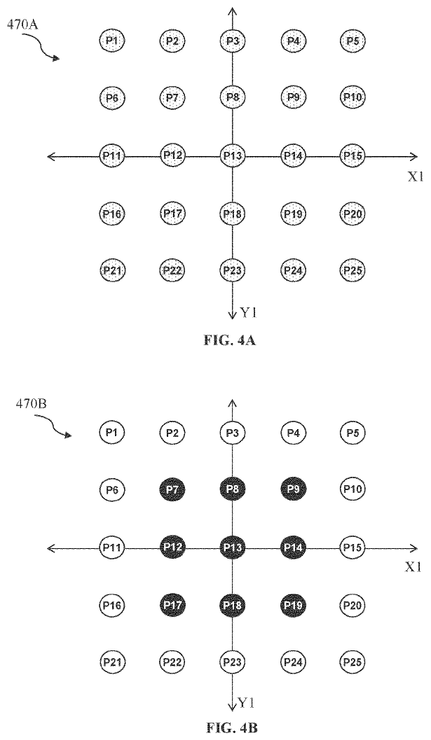

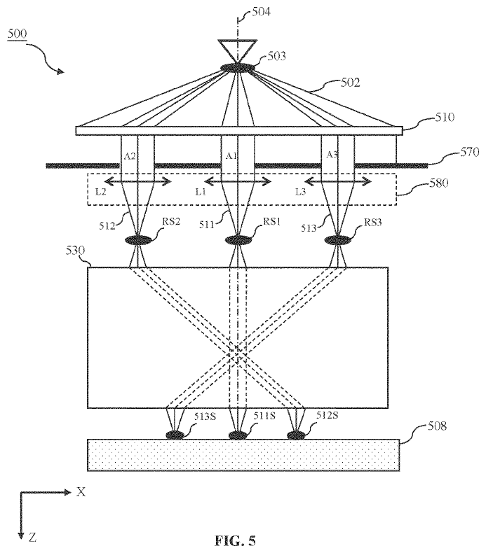

Reference is now made to FIGS. 4A and 4B, which are schematic diagrams (top views) of exemplary configurations of a beam-limit aperture array, consistent with embodiments of the present disclosure. Beam-limit aperture arrays 470A and 470B may be substantially similar to and may perform substantially similar functions as beam-limit aperture array 370 of FIGS. 3A-3C.

FIG. 4A shows a top view of an exemplary beam-limit aperture array 470A comprising a 5×5 rectangular array of beam-limit apertures P1-P25. Beam-limit aperture array 470A may be disposed immediately downstream from the condenser lens assembly (e.g., condenser lens assembly 310 of FIGS. 3A-3C) or immediately downstream from condenser lens 310_2. In some embodiments, beam-limit aperture array 470A may be disposed in a plane orthogonal to primary optical axis 304 such that it is substantially parallel to condenser lens 310_1 and condenser lens 310_2.

In a non-crossover mode of operation, primary electron beam 302 generated from electron source 301 may pass through condenser lens assembly 310 without forming a beam crossover. The beam current of primary electron beam 302 may be adjusted within a range of currents based on the combinations of the settings of condenser lenses of condenser lens assembly 310. For example, low beamlet current of the beam current range may be achieved by focusing and collimating primary electron beam 302 through condenser lens 310_2 while condenser lens 310_1 is deactivated. In such a configuration, primary electron beam 302, after exiting condenser lens assembly 310, may pass through each of the apertures (e.g., apertures P1-P25 of beam-limit aperture array 470A), resulting in a plurality of beamlets having a low beamlet current. Alternatively, higher beamlet current of the beam current range may be achieved by focusing and collimating primary electron beam 302 through condenser lens 310_1, while condenser lens 310_2 is deactivated. In this configuration, primary electron beam 302, after exiting condenser lens assembly 310, may pass through each of the apertures (e.g., apertures P1-P25 of beam-limit aperture array 470A), resulting in a plurality of beamlets having a high beamlet current.

In comparison, in a crossover mode of operation, primary electron beam 302 passing through condenser lens assembly 310 may be focused to form a beam crossover (e.g., beam crossover 315 of FIGS. 3A-3C). The beam current of primary electron beam 302 may be adjusted by varying the electrical excitation, or position, or both of one or more condenser lenses of condenser lens assembly 310. Adjusting the excitation or position of the principal planes of the condenser lenses may adjust the position of beam crossover along primary optical axis 304 and between condenser lens 310_1 and condenser lens 310_2. After the crossover is formed, primary electron beam 302 may be further focused or collimated, traversing through some, but not all, apertures of beam-limit aperture array 470B.

FIG. 4B illustrates a top view schematic of an exemplary beam-limit aperture array 470B comprising a 5×5 rectangular array of beam-limit apertures. As shown, in the crossover mode of operation, primary electron beam 302 after exiting condenser lens 310_2 may pass through apertures P7-P9, P12-P14, and P17-P19 of beam-limit aperture array 470B. Because the condenser lens 310_1 is configured to focus primary electron beam 302 to form a beam crossover (e.g., beam crossover 315 of FIGS. 3A-3C), the primary electron beam is compacted and combined, resulting in a smaller number of beamlets generated, each beamlet having a higher beamlet current in comparison with the non-crossover mode of operation.

In some embodiments, beam-limit aperture array 470B may be aligned with primary optical axis 304 such that the geometric center of aperture P13 coincides with primary optical axis 304. The apertures P1-P25 of beam-limit aperture array 470B may be circular, elliptical, rectangular, or any suitable shape. Beam-limit aperture array 470A, upon receiving primary electron beam 302, may generate an on-axis beamlet (e.g., beamlet 311 of FIG. 3A) and a plurality of off-axis beamlets (e.g., beamlets 312 and 313 of FIG. 3A). With reference to FIG. 4B, beamlet generated from aperture P13 is the on-axis beamlet and beamlets generated from P7, P8, P9, P12, P14, P17, P18, and P19 are the off-axis beamlets. In the crossover mode of operation, the beamlet current of the on-axis beamlet and each of the off-axis beamlets may be substantially similar and the beamlet current of each of the plurality of beamlets may be higher than the beamlet current of the corresponding beamlets in the non-crossover mode. It is to be appreciated that although beam-limit aperture arrays 470A and 470B are shown to have 25 apertures having a uniform pitch, beam-limit aperture arrays may be configured to have fewer or more apertures, having different shapes, sizes, and separated by non-uniform pitches may be used as well, as appropriate.

Reference is now made to FIG. 5, which illustrates a schematic diagram of an exemplary multi-beam apparatus 500, consistent with embodiments of the present disclosure. In comparison with apparatuses 300A, 300B, and 300C, apparatus 500 may additionally comprise a lens array 580 configured to generate a plurality of real images RS1, RS2, and RS3, of primary beam crossover 503. Condenser lens assembly 510 of apparatus 500 may be substantially similar to and may perform substantially similar functions as condenser lens assembly 310 of FIGS. 3A, 3B, or 3C.

In some embodiments, lens array 580 may be disposed downstream from beam-limit aperture array 570 and may comprise a plurality of micro-lenses L1, L2, L3. Beam-limit aperture array 570 may be substantially similar to and may perform substantially similar functions as beam-limit aperture array 470B of FIG. 4B. In some embodiments, beam-limit aperture array 570 may include a plurality of apertures A1, A2, A3. Lens array 580 may be aligned with primary optical axis 304 and beam-limit aperture array 570 such that each micro-lens L1, L2, L3 is aligned with corresponding apertures A1, A2, A3, and is configured to receive and focus primary beamlets 511, 512, 513, respectively, to generate real images of primary beam crossover 503. The real images RS1, RS2, RS3 may be formed on a plane orthogonal to primary optical axis 304 and located between lens array 580 and primary projection optical system 530.

Primary projection optical system 530 may be substantially similar to and may perform substantially similar functions as primary projection optical system 230 of FIG. 2. In the embodiment illustrated in FIG. 5, primary projection optical system 530 may be configured to focus primary beamlets 511, 512, 513 onto a surface of sample 508 and form probe spots 511S, 512S, 513S, respectively, separated by a pitch. As referred to herein, pitch of the probe spots may be defined as the distance between two immediately adjacent probe spots on the surface of a sample (e.g., sample 508).

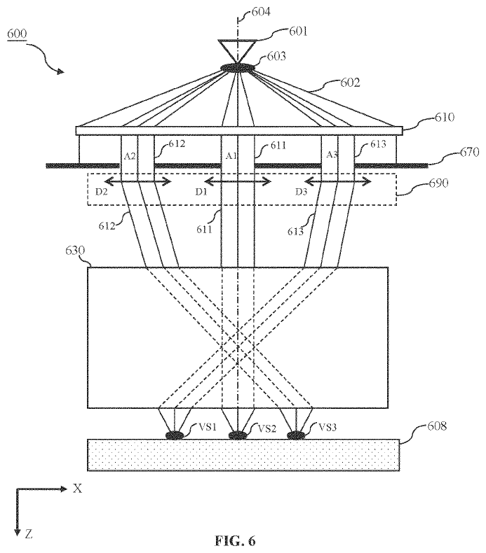

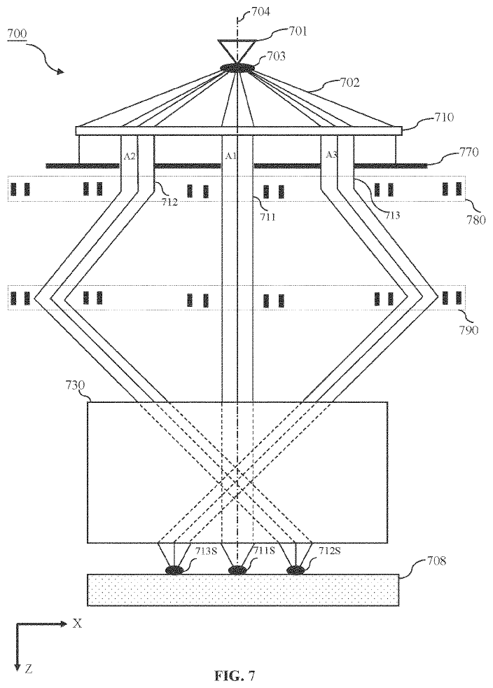

Reference is now made to FIG. 6, which illustrates a schematic diagram of an exemplary multi-beam apparatus 600, consistent with embodiments of the present disclosure. In comparison with apparatuses 300A, 300B, and 300C, apparatus 600 may additionally comprise a deflector array 690 configured to deflect a plurality of beamlets 611, 612, 613 to generate a plurality of virtual images VS1, VS2, VS3 (not shown) of primary beam crossover 603. Condenser lens assembly 610 of apparatus 600 may be substantially similar to and may perform substantially similar functions as condenser lens assembly 310 of FIGS. 3A, 3B, or 3C.

In some embodiments, deflectors D1, D2, and D3 of deflector array 690 may be configured to deflect beamlets 611, 612, 613 by varying angles towards primary optical axis 604. In some embodiments, deflectors farther away from primary optical axis 604 may be configured to deflect beamlets by a greater convergence angle. Furthermore, deflector array 690 may comprise multiple layers (not illustrated), and deflectors may be provided in separate layers. Deflectors may be configured to be individually controlled independent from one another.

In some embodiments, primary projection optical system 630 may be configured to receive deflected plurality of beamlets 611, 612, 613 and focus onto a surface of sample 608 to form a plurality of real images RS1_i, RS2_i, RS3_i, of primary beam crossover 603.

In some embodiments, operating in the crossover mode may generate beamlets having high beamlet current forming probe spots on the sample. If the separation between adjacent probe spots, referred to herein as the pitch, is not large enough, the Coulomb interaction between electrons of two adjacent beamlets may negatively impact the overall achievable image resolution. Therefore, it may be desirable to form the probe spots farther away from each other so that the Coulomb interaction effects are mitigated, while maintaining the high probe currents for individual beamlet.

Reference is now made to FIG. 7, which illustrates a schematic diagram of an exemplary multi-beam apparatus 700, consistent with embodiments of the present disclosure. In comparison with apparatuses 500 and 600, apparatus 700 may additionally, or alternatively, comprise a beam-shift deflector array 780 and an image-forming element array 790. In some embodiments, apparatus 700 may include a source-conversion unit (not illustrated), which may comprise beam-shift deflector array 780 and image-forming element array 790. Condenser lens assembly 710 of apparatus 700 may be substantially similar to and may perform substantially similar functions as condenser lens assembly 310 of FIGS. 3A, 3B, or 3C.

Apparatus 700 may be configured to operate in the crossover mode to generate beamlets having high current or high current density, desirable for voltage-contrast inspection, among other things. Because the individual probe beamlets have higher current density, it may be desirable to increase the pitch of the probe spots formed by high-current probe beamlets to mitigate Coulomb interaction effects which may negatively impact the overall image resolution and defect detection or identification capabilities. Beam-shift deflector array 780 may comprise a plurality of micro-deflectors. Some deflectors of the plurality of micro-deflectors may be configured to deflect incident off-axis beamlets 712 and 713 away from primary optical axis 704, as illustrated in FIG. 7, at a divergence angle based on the excitation of the corresponding deflectors. The on-axis beamlet 711 may pass through an on-axis deflector of beam-shift deflector array 780 undeflected or substantially undeflected. Image-forming element array 790 may be configured to receive beamlets 711, 712, 713 exiting beam-shift deflector array 780.

In some embodiments, image-forming element array 790 may comprise a plurality of micro-deflectors or micro-lenses that may influence plurality of beamlets 711, 712, 713 of primary electron beam 702 and form a plurality of parallel images (virtual or real) of primary beam crossover 703. In some embodiments, though not illustrated here, image-forming element array 790 may comprise multiple layers, and deflectors may be provided in separate layers. A centrally located deflector of image-forming element array 790 may be aligned with primary optical axis 704 of apparatus 700. Thus, in some embodiments, a central deflector may be configured to maintain the trajectory of beamlet 711 to be parallel to primary optical axis 704. In some embodiments, the central deflector may be omitted. However, in some embodiments, primary electron source 701 may not necessarily be aligned with the center of source conversion unit. The off-axis beamlets 712 and 713, after exiting image-forming element array 790, may be incident on the surface of sample 708, forming probe spots 712S and 713S, respectively, such that the pitch of probe spots 711S, 712S, 713S is larger than the pitch of probe spots 511S, 512S, 513S of apparatus 500 of FIG. 5.

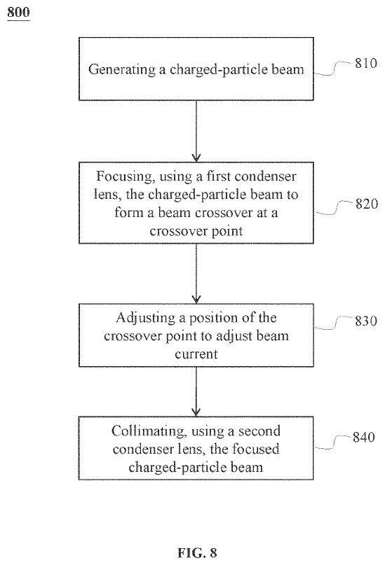

Reference is now made to FIG. 8, which illustrates a process flowchart representing an exemplary method 800 of inspecting a sample using a beam crossover mode in a multi-beam apparatus, consistent with embodiments of the present disclosure. Method 800 may be performed by controller 50 of EBI system 100, as shown in FIG. 1, for example. Controller 50 may be programmed to implement one or more steps of method 800. For example, controller 50 may instruct a module of a charged particle beam apparatus to activate a charged-particle source to generate charged particle beam (e.g., electron beam), to adjust the excitation of one or more condenser lenses to adjust the position of the beam crossover and carry out other functions.

In step 810, a charged-particle source (e.g., electron source 301 of FIG. 3A) may be activated to generate a charged-particle beam (e.g., primary electron beam 302 of FIG. 3A). The electron source may be activated by a controller (e.g., controller 50 of FIG. 1). For example, the electron source may be controlled to emit primary electrons to form an electron beam along a primary optical axis (e.g., primary optical axis 304 of FIG. 3A). The electron source may be activated remotely, for example, by using a software, an application, or a set of instructions for a processor of a controller to power the electron source through a control circuitry.

In step 820, the primary electron beam may be focused to form a beam crossover (e.g., beam crossover 315 of FIG. 3A) at a crossover point along the primary optical axis. In a crossover mode of operation, the electron source may generate the primary electron beam traveling along the primary optical axis. A first condenser lens (e.g., condenser lens 310_1 of FIG. 3A) may receive the primary electron beam and focus the electrons such that the beam forms a crossover at a crossover point along the primary optical axis. The beam crossover may be formed between the first and the second condenser lens of the condenser lens assembly along the primary optical axis.

In step 830, the location of the beam crossover may be adjusted based on an electrical excitation of the first condenser lens. As an example, increasing the focusing power of the first condenser lens by adjusting the applied electrical excitation signal may cause the primary electron beam to converge at a higher angle and to form the beam crossover closer to the electron source along the primary optical axis. In contrast, decreasing the focusing power of condenser lens may cause the primary electron beam to converge at a smaller angle and to form the beam crossover farther from the electron source along primary optical axis.

In some embodiments, the location of the beam crossover, and therefore the beam current of primary electron beam, may be adjusted based on the combination of excitation settings of the first condenser lens and a second condenser lens (e.g., condenser lens 310_2 of FIG. 3A). In some embodiments, the first and the second condenser lens may be electrostatic, magnetic, or compound electromagnetic lenses, or any combination thereof. In some embodiments where the condenser lens is a compound electromagnetic lens, the beam current of the primary electron beam may be further adjusted based on the position of principal planes (e.g., principal planes 310_1P and 310_2P of FIG. 3A) of the condenser lenses.

In step 840, the second condenser lens may further focus and collimate the primary electron beam such that the primary electron beam exits a condenser lens assembly (e.g., condenser lens assembly 310 of FIG. 3A) substantially parallel to the primary optical axis and is incident on a beam-limit aperture array (e.g., beam-limit aperture array 370 of FIG. 3A) substantially perpendicularly. The beam-limit aperture array may be configured to generate beamlets from the primary electron beam and further adjust the beamlet current of individual beamlets, as appropriate. For example, the diameter of the apertures of the beam-limit aperture array may determine the number of electrons that are allowed to pass through and therefore constitute a beamlet. The beamlet current may be determined based on the number of electrons or the diameter of the beamlets generated.

As previously described, voltage-contrast imaging (VCI) includes a two-step process. The first step includes pre-charging a surface of a sample by flooding the surface with charged-particles (e.g., electrons) to highlight the electrical defects and the second step includes inspecting the flooded surface to detect the highlighted defects. To enhance the voltage contrast, the pre-charging step may be performed by exposing the sample surface to a single large current beam or multiple large current beamlets. In the inspection step following the pre-charging step, the sample may be inspected using a small current beam for high resolution imaging. For defect detection by VCI in a SEM, switching between the pre-charging and the inspection modes may include adjusting the beam current, for example, by selecting the aperture size of a Coulomb Aperture Array (CAA). Selecting and aligning apertures to produce the desired beam current may take several seconds and may reduce the overall inspection throughput, among other things. Further, in some cases, such as defect inspection for 3D-NAND devices, the maximum achievable beam current may be insufficient to detect buried electrical defects, rendering the existing VCI technique either inadequate or inefficient, or both. Therefore, for voltage contrast defect detection, it may be desirable to enhance the probe current of each of the probing beamlets such that the sample may be pre-charged and inspected using the same high current beams, eliminating the need to switch between flooding and inspection modes.

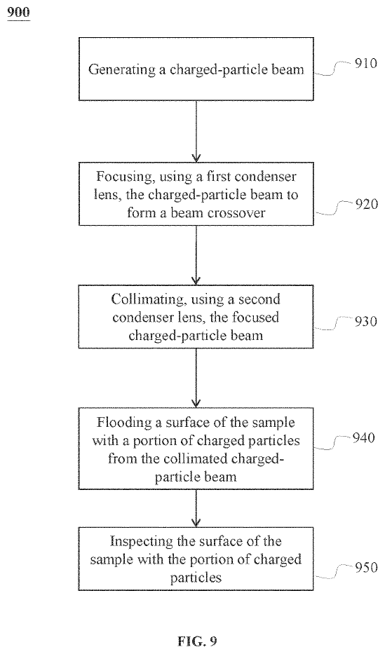

Reference is now made to FIG. 9, which illustrates a process flowchart representing an exemplary method 900 of inspecting a sample using a beam crossover mode in a multi-beam apparatus, consistent with embodiments of the present disclosure. Method 900 may be performed by controller 50 of EBI system 100, as shown in FIG. 1, for example. Controller 50 may be programmed to implement one or more steps of method 900. For example, controller 50 may instruct a module of a charged particle beam apparatus to activate a charged-particle source to generate charged particle beam (e.g., electron beam), to adjust the excitation of one or more condenser lenses to adjust the position of the beam crossover and carry out other functions.

In step 910, a charged-particle source (e.g., electron source 301 of FIG. 3A) may be activated to generate a charged-particle beam (e.g., primary electron beam 302 of FIG. 3A). The electron source may be activated by a controller (e.g., controller 50 of FIG. 1). For example, the electron source may be controlled to emit primary electrons to form an electron beam along a primary optical axis (e.g., primary optical axis 304 of FIG. 3A). The electron source may be activated remotely, for example, by using software, an application, or a set of instructions for a processor of a controller to power the electron source through a control circuitry.

In step 920, the primary electron beam may be focused to form a beam crossover (e.g., beam crossover 315 of FIG. 3A) at a crossover point along the primary optical axis. In a crossover mode of operation, the electron source may generate the primary electron beam traveling along the primary optical axis. A first condenser lens (e.g., condenser lens 310_1 of FIG. 3A) may receive the primary electron beam and focus the electrons such that the beam forms a crossover at a crossover point along the primary optical axis. The beam crossover may be formed between the first and the second condenser lens of the condenser lens assembly along the primary optical axis.

The location of the beam crossover may be adjusted based on an electrical excitation of the first condenser lens. As an example, increasing the focusing power of the first condenser lens by adjusting the applied electrical excitation signal may cause the primary electron beam to converge at a higher angle and to form the beam crossover closer to the electron source along the primary optical axis. In contrast, decreasing the focusing power of condenser lens may cause the primary electron beam to converge at a smaller angle and to form the beam crossover farther from the electron source along primary optical axis.

In step 930, the second condenser lens may further focus and collimate the primary electron beam such that the primary electron beam exits a condenser lens assembly (e.g., condenser lens assembly 310 of FIG. 3A) substantially parallel to the primary optical axis and is incident on a beam-limit aperture array (e.g., beam-limit aperture array 370 of FIG. 3A) substantially perpendicularly. The beam-limit aperture array may be configured to generate beamlets from the primary electron beam and further adjust the beamlet current of individual beamlets, as appropriate. For example, the diameter of the apertures of the beam-limit aperture array may determine the number of electrons that are allowed to pass through and therefore constitute a beamlet. The beamlet current may be determined based on the number of electrons or the diameter of the beamlets generated.

In step 940, a surface of the sample may be flooded with a portion of charged particles from the collimated charged-particle beam to pre-charge the sample surface. Pre-charging or flooding the sample surface with a large current beam may enhance the voltage contrast, which is desirable in detection of electrical defects. The primary charged-particle beam, after the beam crossover, has a high current density because the charged particles are compacted into a smaller size beam. Pre-charging the surface may be performed to highlight the defects or defect regions.

In step 950, the sample surface may be inspected using the portion of charged particles from the collimated charged-particle beam. As previously described, inspection of features of complex structures such as 3D-NAND may require a beam or multiple beams having high probe current. The collimated charged-particle beam having high current density used for flooding the sample surface may be used to inspect the sample surface as well, enabling a single-step process for pre-charging and inspecting a sample surface for voltage-contrast imaging using a SEM.

A non-transitory computer readable medium may be provided that stores instructions for a processor of a controller (e.g., controller 50 of FIG. 1) to carry out image inspection, image acquisition, activating charged-particle source, adjusting the electrical excitation of one or more condenser lens, electrically moving the principal plane of one or more compound electromagnetic lens, moving the sample stage to adjust the position of the sample, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments of the present disclosure may further be described using the following clauses:

1. A multiple charged-particle beam apparatus comprising:
a charged-particle source configured to generate a plurality of charged-particle beams along a primary optical axis;
a first condenser lens configured to focus the plurality of charged-particle beams to form a beam crossover at a crossover point; and
a second condenser lens configured to collimate the focused plurality of charged-particle beams, wherein the crossover point is formed between the first and the second condenser lens relative to the primary optical axis, and wherein an adjustment of a position of the crossover point causes an adjustment of beam sizes of the plurality of charged-particle beams.

2. The multiple charged-particle beam apparatus of clause 1, wherein the first condenser lens comprises a first electrostatic lens or a first electromagnetic lens.

3. The multiple charged-particle beam apparatus of any one of clauses 1 and 2, wherein the position of the crossover point is adjustable based on an excitation of the first condenser lens.

4. The multiple charged-particle beam apparatus of any one of clauses 1-3, wherein the first condenser lens is disposed along a first principal plane substantially perpendicular to the primary optical axis.

5. The multiple charged-particle beam apparatus of clause 4, wherein the position of the crossover point is adjustable based on a position of the first principal plane along the primary optical axis.

6. The multiple charged-particle beam apparatus of any one of clauses 1-5, wherein the second condenser lens comprises a second electrostatic lens or a second electromagnetic lens.

7. The multiple charged-particle beam apparatus of any one of clauses 1-6, wherein the position of the crossover point is adjustable based on a combined excitation of the first and the second condenser lens.

8. The multiple charged-particle beam apparatus of any one of clauses 1-7, wherein the excitation of the second condenser lens is determined based on the excitation of the first condenser lens.

9. The multiple charged-particle beam apparatus of any one of clauses 1-8, wherein the second condenser lens is disposed along a second principal plane substantially perpendicular to the primary optical axis.

10. The multiple charged-particle beam apparatus of clause 9, wherein the position of the crossover point is adjustable based on a position of the second principal plane with respect to the position of the first principal plane.

11. The multiple charged-particle beam apparatus of any one of clauses 1-10, wherein each of the first and the second condenser lens comprises an electrostatic lens.

12. The multiple charged-particle beam apparatus of any one of clauses 1-11, wherein one of the first and the second condenser lens comprises an electrostatic lens and the other comprises an electromagnetic lens.

13. The multiple charged-particle beam apparatus of any one of clauses 1-12, wherein each of the first and the second condenser lens comprises an electromagnetic lens.

14. The multiple charged-particle beam apparatus of any one of clauses 1-13, wherein the second condenser lens is further configured to focus the charged-particle beam onto a beam-limit aperture array located downstream from the second condenser lens.

15. The multiple charged-particle beam apparatus of clause 14, wherein the beam-limit aperture array is configured to generate a plurality of beamlets from the plurality of charged-particle beams exiting the second condenser lens, the plurality of beamlets comprising an on-axis beamlet and a plurality of off-axis beamlets.

16. The multiple charged-particle beam apparatus of clause 15, further comprising a lens array configured to generate a plurality of real images of the charged-particle source from the plurality of beamlets.

17. The multiple charged-particle beam apparatus of clause 15, further comprising a beam deflector array configured to generate a plurality of virtual images of the charged-particle source from the plurality of beamlets.

18. The multiple charged-particle beam apparatus of clause 15, further comprising an objective lens configured to focus the plurality of beamlets onto a surface of a sample and form a first plurality of probe spots on the sample, the first plurality of probe spots separated by a first pitch distance.

19. The multiple charged-particle beam apparatus of clause 18, further comprising a beam-shift deflector array configured to deflect the plurality of off-axis beamlets away from the primary optical axis, wherein the objective lens is further configured to focus the on-axis beamlet and the deflected plurality of off-axis beamlets to form a second plurality of probe spots on the surface of the sample, the second plurality of probe spots separated by a second pitch distance greater than the first pitch distance.

20. A method of inspecting a sample using a multiple charged-particle beam apparatus, the method comprising:
generating a plurality of charged-particle beams along a primary optical axis from a charged-particle source;
focusing, using a first condenser lens, the plurality of charged-particle beams to form a beam crossover at a crossover point;
adjusting a position of the crossover point to adjust beam sizes of the plurality of charged-particle beams; and
collimating, using a second condenser lens, the focused plurality of charged-particle beams, wherein the crossover point is formed between the first and the second condenser lens relative to the primary optical axis.

21. The method of clause 20, wherein adjusting the position of the crossover point further comprises adjusting a position of a first principal plane of the first condenser lens along the primary optical axis.

22. The method of any one of clauses 20 and 21, wherein adjusting the position of the crossover point further comprises adjusting a combined excitation of the first and the second condenser lens.

23. The method of any one of clauses 20-22, wherein adjusting the position of the crossover point comprises adjusting an excitation of the first condenser lens.

24. The method of clause 23, wherein an excitation of the second condenser lens is determined based on the excitation of the first condenser lens.

25. The method of any one of clauses 21-24, wherein adjusting the position of the crossover point further comprises adjusting a position of a second principal plane with respect to the position of the first principal plane.

26. The method of any one of clauses 20-25, further comprising focusing the plurality of charged-particle beams, using the second condenser lens, onto a beam-limit aperture array located downstream from the second condenser lens.

27. The method of clause 26, further comprising generating a plurality of beamlets from the plurality of charged-particle beams incident on the beam-limit aperture array, the plurality of beamlets comprising an on-axis beamlet and a plurality of off-axis beamlets.

28. The method of clause 27, further comprising generating, using a lens array located downstream from the second condenser lens, a plurality of real images of the charged-particle source from the plurality of beamlets.

29. The method of clause 27, further comprising generating, using a deflector array located downstream from the second condenser lens, a plurality of virtual images of the charged-particle source from the plurality of beamlets.

30. The method of clause 27, further comprising focusing, using an objective lens, the plurality of beamlets to form a first plurality of probe spots on a surface of a sample, the first plurality of probe spots separated by a first pitch distance.

31. The method of clause 30, further comprising deflecting, using a beam-shift deflector array, the plurality of off-axis beamlets away from the primary optical axis, wherein the objective lens is further configured to focus the on-axis beamlet and the deflected plurality of off-axis beamlets to form a second plurality of probe spots on the surface of the sample, the second plurality of probe spots separated by a second pitch distance greater than the first pitch distance.

32. A non-transitory computer readable medium storing a set of instructions that is executable by one or more processors of a multiple charged-particle beam apparatus to cause the charged particle beam apparatus to perform a method comprising:
activating a charged-particle source to generate a plurality of charged-particle beams along a primary optical axis;
focusing the plurality of charged-particle beams to form a beam crossover at a crossover point;
adjusting a position of the crossover point to adjust beam sizes of the plurality of charged-particle beams; and
collimating the focused plurality of charged-particle beams, wherein the crossover point is formed between a first and a second condenser lens of a condenser lens assembly and along the primary optical axis.

33. The non-transitory computer readable medium of clause 32, wherein the set of instructions that is executable by one or more processors of the multiple charged-particle beam apparatus causes the multiple charged-particle beam apparatus to further perform adjusting a position of a first principal plane of the first condenser lens along the primary optical axis.

34. The non-transitory computer readable medium of any one of clauses 32 and 33, wherein the set of instructions that is executable by one or more processors of the multiple charged-particle beam apparatus causes the multiple charged-particle beam apparatus to further perform adjusting a combined excitation of the first and the second condenser lens.

35. The non-transitory computer readable medium of any one of clauses 32-34, wherein the set of instructions that is executable by one or more processors of the multiple charged-particle beam apparatus causes the multiple charged-particle beam apparatus to further perform adjusting an excitation of the first condenser lens.

36. The non-transitory computer readable medium of clause 35, wherein the set of instructions that is executable by one or more processors of the multiple charged-particle beam apparatus causes the multiple charged-particle beam apparatus to further perform adjusting an excitation of the second condenser lens based on the excitation of the first condenser lens.

37. The non-transitory computer readable medium of any one of clauses 33-36, wherein the set of instructions that is executable by one or more processors of the multiple charged-particle beam apparatus causes the multiple charged-particle beam apparatus to further perform adjusting a position of a second principal plane with respect to the position of the first principal plane.

38. The non-transitory computer readable medium of any one of clauses 32-37, wherein the set of instructions that is executable by one or more processors of the multiple charged-particle beam apparatus causes the multiple charged-particle beam apparatus to further perform focusing the plurality of charged-particle beams onto a beam-limit aperture array located downstream from the second condenser lens.

39. The non-transitory computer readable medium of clause 38, wherein the set of instructions that is executable by one or more processors of the multiple charged-particle beam apparatus causes the multiple charged-particle beam apparatus to further perform generating a plurality of beamlets from the plurality of charged-particle beams incident on the beam-limit aperture array, the plurality of beamlets comprising an on-axis beamlet and a plurality of off-axis beamlets.

40. The non-transitory computer readable medium of clause 39, wherein the set of instructions that is executable by one or more processors of the multiple charged-particle beam apparatus causes the multiple charged-particle beam apparatus to further perform generating a plurality of real images of the charged-particle source from the plurality of beamlets.

41. The non-transitory computer readable medium of clause 39, wherein the set of instructions that is executable by one or more processors of the multiple charged-particle beam apparatus causes the multiple charged-particle beam apparatus to further perform generating a plurality of virtual images of the charged-particle source from the plurality of beamlets.

42. The non-transitory computer readable medium of clause 39, wherein the set of instructions that is executable by one or more processors of the multiple charged-particle beam apparatus causes the multiple charged-particle beam apparatus to further perform focusing the plurality of beamlets to form a first plurality of probe spots on a surface of a sample, the first plurality of probe spots separated by a first pitch distance.

43. The non-transitory computer readable medium of clause 42, wherein the set of instructions that is executable by one or more processors of the multiple charged-particle beam apparatus causes the multiple charged-particle beam apparatus to further perform deflecting the plurality of off-axis beamlets away from the primary optical axis, wherein the objective lens is further configured to focus the on-axis beamlet and the deflected plurality of off-axis beamlets to form a second plurality of probe spots on the surface of the sample, the second plurality of probe spots separated by a second pitch distance greater than the first pitch distance.

44. A multiple charged-particle beam apparatus comprising:
a charged-particle source configured to generate a plurality of charged-particle beams along a primary optical axis;
a first condenser lens configured to focus the plurality of charged-particle beams to form a beam crossover; and
a second condenser lens configured to collimate the focused plurality of charged-particle beams, wherein the beam crossover is formed between the first and the second condenser lens relative to the primary optical axis, and wherein the collimated plurality of charged-particle beams is used to flood a surface of a sample with charged particles and to inspect the flooded surface of the sample.

45. A method of inspecting a sample using a multiple charged-particle beam apparatus, the method comprising:
generating a plurality of charged-particle beams along a primary optical axis from a charged-particle source;
focusing, using a first condenser lens, the plurality of charged-particle beams to form a beam crossover at a crossover point;
collimating, using a second condenser lens, the focused plurality of charged-particle beams;
flooding a surface of the sample with a portion of charged particles from the collimated plurality of charged-particle beams; and
inspecting the flooded surface using the portion of charged particles.

46. The method of clause 45, further comprising adjusting a position of a first principal plane of the first condenser lens along the primary optical axis to adjust a position of the crossover point.

47. The method of clause 46, wherein adjusting the position of the crossover point further comprises adjusting a combined excitation of the first and the second condenser lens.

48. The method of any one of clauses 46 and 47, wherein adjusting the position of the crossover point further comprises adjusting an excitation of the first condenser lens.

49. The method of clause 48, wherein an excitation of the second condenser lens is determined based on the excitation of the first condenser lens.

50. The method of any one of clauses 46-49, wherein adjusting the position of the crossover point further comprises adjusting a position of a second principal plane with respect to the position of the first principal plane.

51. The method of any one of clauses 45-50, further comprising focusing the plurality of charged-particle beams, using the second condenser lens, onto a beam-limit aperture array located downstream from the second condenser lens.

52. The method of clause 51, further comprising generating a plurality of beamlets from the plurality of charged-particle beams incident on the beam-limit aperture array, the plurality of beamlets comprising an on-axis beamlet and a plurality of off-axis beamlets.

53. The method of clause 52, further comprising generating, using a lens array located downstream from the second condenser lens, a plurality of real images of the charged-particle source from the plurality of beamlets.

54. The method of clause 52, further comprising generating, using a deflector array located downstream from the second condenser lens, a plurality of virtual images of the charged-particle source from the plurality of beamlets.

55. The method of clause 52, further comprising focusing, using an objective lens, the plurality of beamlets to form a first plurality of probe spots on a surface of a sample, the first plurality of probe spots separated by a first pitch distance.

56. The method of clause 55, further comprising deflecting, using a beam-shift deflector array, the plurality of off-axis beamlets away from the primary optical axis, wherein the objective lens is further configured to focus the on-axis beamlet and the deflected plurality of off-axis beamlets to form a second plurality of probe spots on the surface of the sample, the second plurality of probe spots separated by a second pitch distance greater than the first pitch distance.

57. A non-transitory computer readable medium storing a set of instructions that is executable by one or more processors of a multiple charged-particle beam apparatus to cause the charged particle beam apparatus to perform a method comprising:
generating a plurality of charged-particle beams along a primary optical axis from a charged-particle source;
focusing, using a first condenser lens, the plurality of charged-particle beams to form a beam crossover;
collimating, using a second condenser lens, the focused plurality of charged-particle beams;
flooding a surface of the sample with a portion of charged particles from the collimated plurality of charged-particle beams; and
inspecting the flooded surface using the portion of charged particles.

58. The non-transitory computer readable medium of clause 57, wherein the set of instructions that is executable by one or more processors of the multiple charged-particle beam apparatus causes the multiple charged-particle beam apparatus to further perform adjusting a position of a first principal plane of the first condenser lens along the primary optical axis to adjust a position of the crossover point.

59. The non-transitory computer readable medium of any one of clauses 57 and 58, wherein the set of instructions that is executable by one or more processors of the multiple charged-particle beam apparatus causes the multiple charged-particle beam apparatus to further perform adjusting a combined excitation of the first and the second condenser lens.

60. The non-transitory computer readable medium of any one of clauses 57-59, wherein the set of instructions that is executable by one or more processors of the multiple charged-particle beam apparatus causes the multiple charged-particle beam apparatus to further perform adjusting an excitation of the first condenser lens.

61. The non-transitory computer readable medium of clause 60, wherein the set of instructions that is executable by one or more processors of the multiple charged-particle beam apparatus causes the multiple charged-particle beam apparatus to further perform adjusting an excitation of the second condenser lens based on the excitation of the first condenser lens.

62. The non-transitory computer readable medium of any one of clauses 58-61, wherein the set of instructions that is executable by one or more processors of the multiple charged-particle beam apparatus causes the multiple charged-particle beam apparatus to further perform adjusting a position of a second principal plane with respect to the position of the first principal plane.

63. The non-transitory computer readable medium of any one of clauses 57-62, wherein the set of instructions that is executable by one or more processors of the multiple charged-particle beam apparatus causes the multiple charged-particle beam apparatus to further perform focusing the plurality of charged-particle beams onto a beam-limit aperture array located downstream from the second condenser lens.

64. The non-transitory computer readable medium of clause 63, wherein the set of instructions that is executable by one or more processors of the multiple charged-particle beam apparatus causes the multiple charged-particle beam apparatus to further perform generating a plurality of beamlets from the plurality of charged-particle beams incident on the beam-limit aperture array, the plurality of beamlets comprising an on-axis beamlet and a plurality of off-axis beamlets.

65. The non-transitory computer readable medium of clause 64, wherein the set of instructions that is executable by one or more processors of the multiple charged-particle beam apparatus causes the multiple charged-particle beam apparatus to further perform generating a plurality of real images of the charged-particle source from the plurality of beamlets.

66. The non-transitory computer readable medium of clause 64, wherein the set of instructions that is executable by one or more processors of the multiple charged-particle beam apparatus causes the multiple charged-particle beam apparatus to further perform generating a plurality of virtual images of the charged-particle source from the plurality of beamlets.

67. The non-transitory computer readable medium of clause 64, wherein the set of instructions that is executable by one or more processors of the multiple charged-particle beam apparatus causes the multiple charged-particle beam apparatus to further perform focusing the plurality of beamlets to form a first plurality of probe spots on a surface of a sample, the first plurality of probe spots separated by a first pitch distance.

68. The non-transitory computer readable medium of clause 67, wherein the set of instructions that is executable by one or more processors of the multiple charged-particle beam apparatus causes the multiple charged-particle beam apparatus to further perform deflecting the plurality of off-axis beamlets away from the primary optical axis, wherein the objective lens is further configured to focus the on-axis beamlet and the deflected plurality of off-axis beamlets to form a second plurality of probe spots on the surface of the sample, the second plurality of probe spots separated by a second pitch distance greater than the first pitch distance.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A multiple charged-particle beam apparatus comprising:
a charged-particle source configured to generate a plurality of charged-particle beams along a primary optical axis;
a first condenser lens configured to focus the plurality of charged-particle beams to form a beam crossover at a crossover point; and
a second condenser lens configured to collimate the focused plurality of charged-particle beams,
wherein the crossover point is formed between the first and the second condenser lens relative to the primary optical axis, and
wherein an adjustment of a position of the crossover point causes an adjustment of beam sizes of the plurality of charged-particle beams.

2. The multiple charged-particle beam apparatus of claim 1, wherein the first condenser lens comprises a first electrostatic lens or a first electromagnetic lens.

3. The multiple charged-particle beam apparatus of claim 1, wherein the position of the crossover point is adjustable based on an excitation of the first condenser lens.

4. The multiple charged-particle beam apparatus of claim 1, wherein the first condenser lens is disposed along a first principal plane substantially perpendicular to the primary optical axis.

5. The multiple charged-particle beam apparatus of claim 4, wherein the position of the crossover point is adjustable based on a position of the first principal plane along the primary optical axis.

6. The multiple charged-particle beam apparatus of claim 1, wherein the second condenser lens comprises a second electrostatic lens or a second electromagnetic lens.

7. The multiple charged-particle beam apparatus of claim 1, wherein the position of the crossover point is adjustable based on a combined excitation of the first and the second condenser lens.

8. The multiple charged-particle beam apparatus of claim 7, wherein the excitation of the second condenser lens is determined based on the excitation of the first condenser lens.

9. The multiple charged-particle beam apparatus of claim 1, wherein the second condenser lens is disposed along a second principal plane substantially perpendicular to the primary optical axis.

10. The multiple charged-particle beam apparatus of claim 9, wherein the position of the crossover point is adjustable based on a position of the second principal plane with respect to a position of a first principal plane that is relative to the first condenser lens.

11. The multiple charged-particle beam apparatus of claim 1, wherein each of the first and the second condenser lens comprises an electrostatic lens.

12. The multiple charged-particle beam apparatus of claim 1, wherein one of the first and the second condenser lens comprises an electrostatic lens and the other comprises an electromagnetic lens.

13. The multiple charged-particle beam apparatus of claim 1, wherein each of the first and the second condenser lens comprises an electromagnetic lens.

14. The multiple charged-particle beam apparatus of claim 1, wherein the second condenser lens is further configured to focus the charged-particle beam onto a beam-limit aperture array located downstream from the second condenser lens.

15. A non-transitory computer readable medium storing a set of instructions that is executable by one or more processors of a multiple charged-particle beam apparatus to cause the charged particle beam apparatus to perform a method comprising:
activating a charged-particle source to generate a plurality of charged-particle beams along a primary optical axis;
focusing the plurality of charged-particle beams to form a beam crossover at a crossover point;
adjusting a position of the crossover point to adjust beam sizes of the plurality of charged-particle beams; and
collimating the focused plurality of charged-particle beams,
wherein the crossover point is formed between a first and a second condenser lens of a condenser lens assembly and along the primary optical axis.

16. The non-transitory computer readable medium of claim 15, wherein the set of instructions that is executable by one or more processors of the multiple charged-particle beam apparatus causes the multiple charged-particle beam apparatus to further perform adjusting a position of a first principal plane of the first condenser lens along the primary optical axis.

17. The non-transitory computer readable medium of claim 15, wherein the set of instructions that is executable by one or more processors of the multiple charged-particle beam apparatus causes the multiple charged-particle beam apparatus to further perform adjusting a combined excitation of the first and the second condenser lens.

18. The non-transitory computer readable medium of claim 15, wherein the set of instructions that is executable by one or more processors of the multiple charged-particle beam apparatus causes the multiple charged-particle beam apparatus to further perform adjusting an excitation of the first condenser lens.

19. The non-transitory computer readable medium of claim 19, wherein the set of instructions that is executable by one or more processors of the multiple charged-particle beam apparatus causes the multiple charged-particle beam apparatus to further perform adjusting an excitation of the second condenser lens based on the excitation of the first condenser lens.

20. The non-transitory computer readable medium of claim 15, wherein the set of instructions that is executable by one or more processors of the multiple charged-particle beam apparatus causes the multiple charged-particle beam apparatus to further perform adjusting a position of a second principal plane with respect to a position of a first principal plane that is relative to the first condenser lens.
